(19) United States
(12) Patent Application Publication
(10) Pub. No.: US 2025/0130067 A1
(43) Pub. Date: Apr. 24, 2025

(54) Map Service Providing Method and Map Service Providing System Based on Autonomous Driving Simulation Testing

(71) Applicant: Robert Bosch GmbH, Stuttgart (DE)

(72) Inventors: Anping Mao, Suzhou (CN); Yin Cheng, Suzhou (CN); Shaokun Sui, Suzhou (CN); Yue Li, Suzhou (CN)

(21) Appl. No.: 18/917,691

(22) Filed: Oct. 16, 2024

(30) Foreign Application Priority Data
Oct. 23, 2023 (CN) 2023 1138 0344.5

(51) Int. Cl. G01C 21/00; G05B 17/02

(52) U.S. Cl. CPC G01C 21/3837; G01C 21/387; G01C 21/3896; G05B 17/02

(57) ABSTRACT

A map service providing method and a map service providing system based on autonomous driving simulation testing is disclosed. The method includes: building a test scenario using an emulator and converting the test scenario to a first format of map data; uploading the first format of map data to a map server; downloading, by a server, the first format of map data from the map server in the case that the server requires to access to the first format of map data; uploading, by the emulator, own-vehicle positioning information to the server; obtaining, by a map engine, the own-vehicle positioning information from the server and obtaining own-vehicle surrounding road network information according to parsing of the own-vehicle positioning information and the first format of map data; generating, by the map engine, a planning path according to a simulation origin and a simulation endpoint; converting, by the map engine, the own-vehicle surrounding road network information and the planning path to a second format of map data and returning the second format of map data to the server; and obtaining, by the server, the second format of map data and providing the second format of map data as a map service to the emulator.

This application claims priority under 35 U.S.C. § 119 to patent application no. CN 2023 1138 0344.5, filed on Oct. 23, 2023 in China, the disclosure of which is incorporated herein by reference in its entirety.

The present application relates to autonomous driving simulation testing techniques, and particularly relates to a map service providing method and a map service providing system based on autonomous driving simulation testing.

### BACKGROUND

Autonomous driving simulation testing is mainly to digitally restore an application scenario of autonomous driving in a form of mathematical modeling, build a system model that is as close to the real world as possible, and achieve the objectives of testing and validating autonomous driving systems and algorithms through simulation testing directly through software without field tests.

High-precision maps are increasingly dominant in autonomous driving simulation testing. In the prior art, when a simulation scenario is built, only map data in Opendrive (Opendrive is the main open format and de facto standard describing a road network in a driving simulation application, and is an international high-definition map standard map) format is supported to be imported and exported, while map data in NDS (NDS: Navigation Data Standard, which is a navigation electronic map storage standard) format is not supported. Therefore, when the simulation scenario is built in the prior art, it is common to convert map data in NDS format acquired and built according to real roads to map data in Opendrive format, and then the map data in Opendrive format is imported through simulation software, thereby conducting scenario building for simulation testing.

However, the above approaches often raise a series of problems:
(1) the conversion of two types of map data relies heavily on the support of map providers, which requires significant human and material resources;
(2) representations of map information by NDS and Opendrive belong two dimensions, and problems such as element loss and element mismatches often occur after the conversion;
(3) because opendrive element formats built by various emulators and map providers are not completely uniform, causing the incapability of direct import of emulator software and the poor compatibility;
(4) NDS is real network data with insufficient scenario coverage, so that the test demand of edge scenarios cannot be met, and the flexibility is insufficient;
(5) common emulator software is incapable of outputting all road network information required by an autonomous driving module, causing the incapability of conducting comprehensive testing on the features involved in maps;
(6) and an NDS-based map service can only be used for real vehicle testing and cannot be used for simulation testing.

### SUMMARY

Based on the problems in the prior art described above, the present disclosure is intended to provide a map service providing method and a map service providing system based on autonomous driving simulation testing, which are capable of solving the above problems.

A map service providing method based on autonomous driving simulation testing in one aspect of the present disclosure is implemented using an emulator, a map server, a server, and a map engine, comprising:
a scenario building step, wherein the emulator is used for building a test scenario and converting the test scenario to a first format of map data;
a map uploading step, wherein the first format of map data is uploaded to the map server;
a map downloading step, wherein the server downloads the first format of map data from the map server in the case that the server requires to access to the first format of map data;
an own-vehicle positioning step, wherein the emulator uploads own-vehicle positioning information to the server;
a map parsing step, wherein the map engine obtains the own-vehicle positioning information from the server and obtains own-vehicle surrounding road network information according to parsing of the own-vehicle positioning information and the first format of map data;
a route generation step, wherein the map engine generates a planning path according to a simulation origin and a simulation endpoint, wherein the simulation origin and the simulation endpoint are disposed in the emulator and provided to the map engine via the server by uploading to the server;
a map data conversion step, wherein the map engine converts the own-vehicle surrounding road network information and the planning path to a second format of map data and returns the second format of map data to the server; and
a map service providing step, wherein the server obtains the second format of map data and provides the second format of map data as a map service to the emulator.

A map service providing system based on autonomous driving simulation testing in one aspect of the present disclosure comprises an emulator, a map server, a server, and a map engine,
wherein the emulator is used for building a test scenario and converting the test scenario to a first format of map data, the emulator is also used for uploading the first format of map data to the map server, and used for acquiring own-vehicle positioning information, a simulation origin and a simulation endpoint and uploading the own-vehicle positioning information, the simulation origin and the simulation endpoint to the server;
the map server is used for storing the first format of map data;
the server is used for downloading the first format of map data from the map server and providing the first format of map data to the map engine, used for providing the own-vehicle positioning information, the simulation origin, and the simulation endpoint from the emulator to the map engine, and also used for providing a second format of map data as described below returned from the map engine as a map service to the emulator;
the map engine obtains own-vehicle surrounding road network information according to parsing of the own-vehicle positioning information and the first format of map data obtained from the server; and the map engine generates a planning path according to the simulation origin and the simulation endpoint obtained from the server, and further converts the own-vehicle surrounding road network information and the planning path to the second format of map data and returns the second format of map data to the server.

### BRIEF DESCRIPTION OF THE DRAWINGS

The foregoing and other objectives and advantages of the present application will become more fully apparent from the following detailed description taken in conjunction with the accompanying drawings, in which identical or similar elements are denoted by the same reference numerals.

FIG. 1 is a flow diagram of a map service providing method based on autonomous driving simulation testing according to one embodiment of the present disclosure.

FIG. 2 is a structural block diagram of a map service providing system based on autonomous driving simulation testing according to one embodiment of the present disclosure.

### DETAILED DESCRIPTION

The following are some of the examples of the present disclosure, which are intended to provide a basic understanding of the present disclosure, and are not intended to confirm the key or decisive elements of the present disclosure or to define the scope of protection.

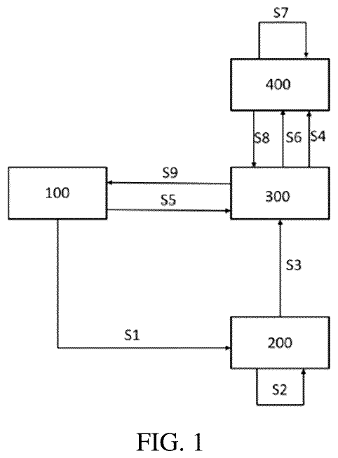

FIG. 1 is a flow diagram of a map service providing method based on autonomous driving simulation testing according to one embodiment of the present disclosure.

As shown in FIG. 1, the map service providing method based on autonomous driving simulation testing according to one embodiment of the present disclosure is implemented using an emulator 100, a map server 200, a server 300, and a map engine 400, the method comprising the following steps:
S1: building a test scenario using the emulator 100 and converting the test scenario to a first format of map data, and uploading the first format of map data to the map server 200;
S2: storing, by the map server 200, the first format of map data;
S3: downloading, by the server 300, the first format of map data from the map server 200 in the case that the server 300 requires to access to the first format of map data stored in the map server 200;
S4: providing, by the server 300, the first format of map data to the map engine 400;
S5: uploading, by the emulator 100, own-vehicle positioning information in real time to the server 300 and providing a simulation origin and a simulation endpoint from the emulator 100 to the server 300;
S6: providing, by the server 300, the own-vehicle positioning information, the simulation origin and the simulation endpoint to the map engine 400;
S7: obtaining, by the map engine 400, the own-vehicle positioning information from the server 300 and obtaining own-vehicle surrounding road network information according to parsing of the own-vehicle positioning information and the first format of map data; generating, by the map engine 400, a planning path according to the simulation origin and the simulation endpoint; and further, converting, by the map engine 400, the own-vehicle surrounding road network information and the generated planning path to a second format of map data;
S8: returning, by the map engine, the converted second format of map data to the server 300;
S9: providing, by the server 300, the obtained second format of map data as a map service to the emulator 100.

Here, the first format of map data is map data in Opendrive format, and the second format of map data is map data in PNC format (Planning And Control), i.e., interface protocols that satisfy PNC definitions, e.g., that may be protobuf, json, xml, etc.

In step S1, the emulator 100 can use emulators such as Carmaker (Carmaker is dynamics ADAS and autonomous driving simulation software released by German IPG company) and VTD (Virtual Test Drive is complex traffic environment vision modeling and simulation software developed by German VIRES company), which can be used to generate and convert to obtain map data in Opendrive format.

The emulator 100 may be disposed on a user end, i.e., on an own vehicle. A simulation origin and a simulation endpoint at the time of simulations may be set by a user, for example, they are set in corresponding configuration files of the emulator 100. A “planning route” generated in S7 above only contains broad road information. In the simulation process of receiving the “planning route” converted to a second format, the own vehicle drives according to planning route information. During the driving process, it is also necessary to obtain surrounding static map information of lane lines, obstacles, peripheral traffic signs, etc. for navigation planning at a lane line level. The static map information refers to the above “own-vehicle surrounding road network information”.

In step S2, the map data can be managed by introducing the map server 200, which can support the upload of the map data in Opendrive format. As a preferred way, the map server 200 is capable of further generating a thumbnail of the map data in Opendrive format automatically for the user to view visually.

In step S3, preferably, the server 300 may be set to perform an identity authentication before the map data is loaded from the map server 200, and is capable of downloading the map data from the map server 200 only in the case that the identity authentication is successful. In particular, for example, the map server 200 issues an appID (application ID) and an appSecret (application key) to the server 300; and in the case that the server 300 accesses to the map server 200, the server 300 obtains a request token through the appID and the appSecret to complete an authentication, and the server 300 is capable of downloading the map data from the map server 200 after the authentication is successful.

The map service providing method based on autonomous driving simulation testing according to an embodiment of the present disclosure is illustrated above, and then a corresponding map service providing system based on autonomous driving simulation testing for implementing the method is illustrated.

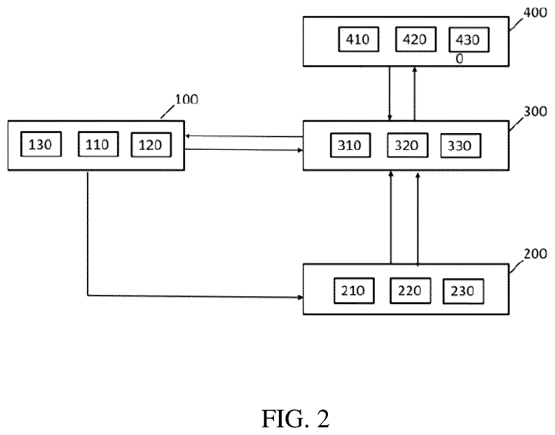

FIG. 2 is a structural block diagram of a map service providing system based on autonomous driving simulation testing according to one embodiment of the present disclosure.

As shown in FIG. 2, the map service providing system based on autonomous driving simulation testing according to an embodiment of the present disclosure comprises: an emulator 100, a map server 200, a server 300, and a map engine 400.

The emulator 100 is disposed at a user end, and used for building a test scenario and converting the test scenario to a first format of map data; and the emulator 100 is also used for uploading the first format of map data to the map server 200, and used for acquiring own-vehicle positioning information, a simulation origin and a simulation endpoint and uploading the own-vehicle positioning information, the simulation origin and the simulation endpoint to the server 300.

The map server 200 is used for storing the first format of map data, and the map server 200 provides API interfaces for the upload, download, and retrieval functions of a map.

The server 300 is used for downloading the first format of map data from the map server 200 and providing the first format of map data to the map engine 400, is used for providing own-vehicle positioning information, a simulation origin, and a simulation endpoint from the emulator 100 to the map engine 400, and is also used for providing a second format of map data as described below returned from the map engine 400 as a map service to the emulator 100, i.e., the server 300 provides all API interfaces required by the emulator 100.

The map engine 400 obtains the own-vehicle surrounding road network information according to parsing of the own-vehicle positioning information and the first format of map data obtained from the server 300; and the map engine 400 generates a planning path according to the simulation origin and the simulation endpoint obtained from the server, and further converts the planning path to the second format of map data and returns the second format of map data to the server 300.

The first format of map data is map data in Opendrive format, and the second format of map data is map data in PNC format (Planning And Control).

The emulator 100 comprises:
a simulation module 110 for acquiring own-vehicle positioning information, a simulation origin, and a simulation endpoint and for building a test scenario and converting the test scenario into a first format of map data and uploading the first format of map data to a map server;
an SDK module 120 for obtaining the own-vehicle positioning information, the simulation origin, and the simulation endpoint from the simulation module 110 and uploading the own-vehicle positioning information, the simulation origin, and the simulation endpoint to the server 300, and for receiving and caching a second format of map data from the server 300 and returning the second format of map data to the simulation module 110; and
a communication module 130 for communicating with the simulation module 110 and for implementing PNC (Planning And Control) functions, FCT (Function Control) functions, and Fusion (sensor data fusion) functions, wherein the PNC functions are used for obtaining the second format of map data returned from the server 300 to the simulation module 110 by communicating with the simulation module 110, i.e. the map data in PNC format and for implementing planning and control of simulations based on the map data in the PNC format.

The SDK module 120 is further capable of having data management functions, including, in particular the reduction of a frequency of requesting the server 300 for loading map data from the map server 200 by controlling an update mechanism for cached content.

The map server 200 comprises:
a storage module 210 for storing a first format of map data obtained from an emulator 100;
a first authentication module 220 for implementing an identity authentication with the server 300; and
a management module 230 for generating a thumbnail of the first format of map data and providing the thumbnail to the server 300 for loading.

The server 300 comprises:
a downloading module 310 for downloading the first format of map data from the map server 200 and providing the first format of map data to the map engine 400; and
a transmission module 320 for providing the own-vehicle positioning information, the simulation origin, and the simulation endpoint from the emulator to the map engine 400, and providing the second format of map data described as below returned from the map engine 400 as a map service to the emulator 100; and
a second authentication module 330 for implementing an identity authentication with the map server 200.

The map engine 400 comprises:
a resolution module 410 for obtaining the own-vehicle surrounding road network information according to parsing of the own-vehicle positioning information and the first format of map data obtained from the server 300 and returning the own-vehicle surrounding road network information to the server 300. During the driving process, it is also necessary to obtain surrounding static map information of lane lines, obstacles, peripheral traffic signs, etc. for navigation planning at a lane line level. These static map information refers to the above “own-vehicle surrounding road network information”;
a path generation module 420 for generating the planning path according to the simulation origin and the simulation endpoint obtained from the server 300; and
a conversion module 430 for converting the own-vehicle surrounding road network information and the planning path to the second format of map data and returning the second format of map data to the server 300.

The present disclosure also provides a computer-readable medium having stored thereon a computer program, and the computer program, when executed by a processor, implements the above map service providing method based on autonomous driving simulation testing.

The present disclosure also provides a computer device, comprising a storage module, a processor, and a computer program stored on the storage module and capable of running on the processor, and the processor, when executing the computer program, implements the above map service providing method based on the autonomous driving simulation testing.

The map service providing method and the map service providing system based on autonomous driving simulation testing according to the present disclosure provide a map service architecture based on Opendrive format and build a map data closed loop chain: Emulator->Map Server->Server->Map Engine->->Server->Emulator. Moreover, Opendrive is an international high-definition map standard that supports the parsing of map services in Opendrive format with extremely high compatibility and scalability.

Further, the map service providing method and the map service providing system based on autonomous driving simulation testing according to the present disclosure can also provide real-time own-vehicle surrounding road network information, making up the limitation that the emulator can only output map information.

Further, according to the map service providing method and the map service providing system based on autonomous driving simulation testing of the present disclosure, the map data can be managed by introducing the map server, thereby be capable of supporting the upload of the map data in Opendrive format and the automatic generation of the thumbnail, so that the user can view it directly. Moreover, the same map data is shared between the emulator and the map server, whereby being capable of ensuring consistency of the data and avoiding mutual conversion between NDS format and Opendrive format, thereby avoiding a series of mismatches caused by data conversion.

Moreover, in the present disclosure, the map in the map server is a self-built map, which exceeds the restrictions based on the NDS map, can cover a variety of core case scenarios, and has greater flexibility.

Further, the map service providing method and the map service providing system based on autonomous driving simulation testing according to the present disclosure solve the problem of the lack of available map services in current autonomous driving simulation testing.

The above descriptions are only specific embodiments of the present application, but the scope of protection of the present application is not limited thereto. Those skilled in the art may contemplate other feasible modifications or substitutions according to the technical scope disclosed in the present application, and all such modifications or substitutions fall within the scope of protection of the present application. Without conflicts, the embodiments of the present application and the features in the embodiments may also be combined. The scope of protection of the present application is subject to the scope of protection of the claims.

### Additional Concepts

Concept 1. A map service providing system based on autonomous driving simulation testing, characterized by comprising: an emulator, a map server, a server, and a map engine,
wherein the emulator is used for building a test scenario and converting the test scenario to a first format of map data, the emulator is also used for uploading the first format of map data to the map server and used for acquiring own-vehicle positioning information, a simulation origin and a simulation endpoint and uploading the own-vehicle positioning information, the simulation origin and the simulation endpoint to the server, and the emulator is also used for receiving a second format of map data as described below from the server;
the map server is used for storing the first format of map data;
the server is used for downloading the first format of map data from the map server and providing the first format of map data to the map engine, used for providing the own-vehicle positioning information, the simulation origin, and the simulation endpoint from the emulator to the map engine, and also used for providing a second format of map data as described below returned from the map engine as a map service to the emulator;
the map engine obtains own-vehicle surrounding road network information according to parsing of the own-vehicle positioning information and the first format of map data obtained from the server; and the map engine generates a planning path according to the simulation origin and the simulation endpoint obtained from the server, and further converts the own-vehicle surrounding road network information and the planning path to the second format of map data and returns the second format of map data to the server.

Concept 2. The map service providing system based on autonomous driving simulation testing according to Concept 1, characterized in that the map server comprises:
a storage module for storing the first format of map data obtained from the emulator, and
a first authentication module for implementing an identity authentication with the server;
and the server further comprises:
a second authentication module for implementing an identity authentication with the map server.

Concept 3. The map service providing system based on autonomous driving simulation testing according to Concept 2, characterized in that
the first format of map data is map data in Opendrive format, and the second format of map data is map data in PNC format.

Concept 4. An emulator, characterized in that the emulator comprises
a simulation module for acquiring own-vehicle positioning information, a simulation origin and a simulation endpoint, and used for building a test scenario and converting the test scenario to a first format of map data;
an SDK module for acquiring the first format of map data from the simulation module and uploading the first format of map data to an external server, and used for returning a second format of map data received from an external server to the simulation module; and
a communication module for obtaining the second format of map data by communicating with the simulation module and used for implementing planning and control of simulations based on the second format of map data.

Concept 5. A map engine, characterized in that the map engine comprises
a resolution module for obtaining own-vehicle surrounding road network information according to parsing of received own-vehicle positioning information and a first format of map data;
a path generation module for generating a planning path according to a received simulation origin and simulation endpoint; and
a conversion module for converting the own-vehicle surrounding road network information and the planning path to a second format of map data.

What is claimed is:

1. A map service providing method based on autonomous driving simulation testing, wherein the method is implemented using an emulator, a map server, a server, and a map engine, comprising:
performing a scenario building step, wherein the emulator is used for building a test scenario and converting the test scenario to a first format of map data;
performing a map uploading step, wherein the first format of map data is uploaded to the map server;
performing a map downloading step, wherein the server downloads the first format of map data from the map server in the case that the server requires to access to the first format of map data;
performing an own-vehicle positioning step, wherein the emulator uploads own-vehicle positioning information to the server;
performing a map parsing step, wherein the map engine obtains the own-vehicle positioning information from the server and obtains own-vehicle surrounding road network information according to parsing of the own-vehicle positioning information and the first format of map data;
performing a route generation step, wherein the map engine generates a planning path according to a simulation origin and a simulation endpoint, wherein the simulation origin and simulation endpoint are disposed in the emulator and provided to the map engine via the server by uploading to the server;
performing a map data conversion step, wherein the map engine converts the own-vehicle surrounding road network information and the planning path to a second format of map data and returns the second format of map data to the server; and
performing a map service providing step, wherein the server obtains the second format of map data and provides the second format of map data as a map service to the emulator.

2. The map service providing method based on autonomous driving simulation testing according to claim 1, wherein:
the first format of map data is map data in Opendrive format, and the second format of map data is map data in PNC format.

3. The map service providing method based on autonomous driving simulation testing according to claim 1, wherein:
in the map downloading step, the server requires to perform an identity authentication before downloading the map data from the map server and is configured to download the map data from the map server only in the case that the identity authentication is successful.

4. A map service providing method based on autonomous driving simulation testing, wherein the method is applied to an emulator, comprising:
acquiring own-vehicle positioning information, a simulation origin, and a simulation endpoint, building a test scenario and converting the own-vehicle positioning information, the simulation origin, and the simulation endpoint to a first format of map data;
uploading the converted first format of map data to an external server;
receiving a second format of map data returned from the external server, wherein the second format of map data is obtained via format conversion on the first format of map data; and
implementing planning and control of simulations based on the second format of map data.

5. A map service providing method of autonomous driving simulation testing, wherein the method is applied to a map engine, comprising:
obtaining own-vehicle surrounding road network information according to parsing of received own-vehicle positioning information and a first format of map data;
generating a planning path according to a received simulation origin and simulation endpoint; and
converting the own-vehicle surrounding road network information and the planning path to a second format of map data.

6. A computer readable medium having stored thereon a computer program,
wherein the computer program, when executed by a processor, implements the map service providing method based on autonomous driving simulation testing according to claim 1.

7. A computer device, comprising a storage module, a processor, and a computer program stored on the storage module and capable of running on the processor, wherein the processor, when executing the computer program, implements the map service providing method based on the autonomous driving simulation testing according to claim 1.
